(19) United States
(12) Patent Application Publication
(10) Pub. No.: US 2024/0243043 A1
(43) Pub. Date: Jul. 18, 2024

(54) CIRCUITRY PACKAGE FOR POWER APPLICATIONS

(71) Applicant: Telefonaktiebolaget LM Ericsson (publ), Stockholm (SE)

(72) Inventors: David SYCHALEUN, Ottawa (CA); Igor ACIMOVIC, Gatineau (CA)

(21) Appl. No.: 18/560,149

(22) PCT Filed: May 12, 2021
(86) PCT No.: PCT/IB2021/054069

§ 371 Date: Nov. 10, 2023

(51) Int. Cl. H01L 23/495; H01L 23/00; H05K 1/02; H05K 1/18

(52) U.S. Cl. CPC H01L 23/49568; H01L 23/49541; H05K 1/0203; H05K 1/181; H01L 24/48; H01L 2224/48175; H05K 2201/066

(57) ABSTRACT

According to one or more embodiments, a circuitry package is positioned on a printed circuit board, (PCB) and a heat sink is provided. The circuitry package includes a body portion having a first surface, and a plurality of leads on a logical plane and affixed on the first surface of the body portion where the plurality of leads are positionable to make contact with the PCB. The circuitry package includes a central paddle affixed to the body portion and extending in a direction substantially perpendicular to the logical plane where the central paddle is configured to support at least one transistor die near the logical plane and act as a thermal interface between the at least one transistor die and the heat sink.

### TECHNICAL FIELD

Electronic circuitry packages, and in particular a circuitry package for use in power amplifiers such as those used in wireless communications.

### BACKGROUND

Network nodes rely on power amplifiers to perform one or more functions such as wireless transmission. Power amplifiers are a challenging area in a network node radio since the power amplifiers may be required to meet stringent performance requirements such as gain, output power and efficiency etc., while at the same time, careful thermal consideration may be needed in order to properly manage the heat that the power amplifier generates, which may be in addition to the extreme outdoor temperature environment. The power amplifier may still need to be linearizable by the digital predistortion (DPD) to meet the out-of-band emission requirement. Further, the power amplifier may also be required to meet an aggressive cost target which may be at least in part dictated by the packaging design. These various factors lead to the importance of high-performance and low-cost power transistor package.

In network node radios where a power amplifier branch typically provides 40 Watts or more average output power (classified as high-power range), an air-cavity plastic (ACP) package is widely used for power transistor packaging. The ACP package power transistor consists of several components, namely, the flange, window frame, input and output leads, and a cover lid as shown in FIG. 1. As illustrated in FIG. 1, the ACP package power transistor 10 (also referred to as ACP package 10) requires several dedicated manufacturing steps to bring to completion, such as window-frame 16 attachment (onto the flange 14), input/output lead 20 attachment, transistor die 12 attachment, wire-bonding of bond wires 18 and finally the lid 22 sealing. All the package components and the manufacturing steps add cost to the overall ACP package 10. That is, the ACP package 10 consists of several parts and hence requires a few dedicated manufacturing processes to complete, this adds cost to the overall ACP package 10. In fact, the majority cost of the ACP package 10 is due to the packaging and manufacturing cost but not the power transistor die 12/IPD itself.

In mounting of ACP package 10, a slot with proper size is cut out of the printed circuit board (PCB) in order to “house” the ACP package 10. FIG. 2 is a cross-sectional view of a portion of ACP package based device 23 where ACP package 10 is mounted onto a PCB 24. The ACP package 10 is mounted onto the carrying PCB 24 by having the input/output leads 20 soldered to the top side of the PCB 24 (i.e., soldered to traces on the PCB 24) while the flange 14 is soldered directly to the heat sink 26. This allows ACP package 10 to achieve good heat dissipation.

Beside the high packaging cost, another drawback of ACP package 10 is the use of the window frame 16 which results in package parasitics. Since the window frame 16 is typically made of dielectric material, the area where input/output leads 20 —window frame 16— flange 14 overlap forms a parallel plate capacitor. Effectively, this results in a shunt package capacitance at both the input and the output side of ACP package 10. These shunt package capacitances disadvantageously limit the transistor performance and cause bandwidth limiting for wideband power amplifier.

On the other hand, in Active Antenna System (AAS) radios where power amplifier branch typically provides 10˜15 Watts range of average output power (mid power range), the plastic overmold Quad Flat No-leads (QFN) type package is often used. The QFN package was originally designed for low power applications and the package design was optimized for low package parasitics as well as low manufacturing cost. The QFN package makes uses of all four sides of the package. If only two sides are needed/used, this is referred to a DFN package or Dual Flat No—lead package. However, as used below, QFN may be used as a generic terminology that may correspond to QFN, DFN, etc.

Manufacturing steps for QFN packaging may start with the desired bare lead frame where die attachment and wire bonding are immediately performed. Afterward, the whole strip is undergone mold encapsulation and eventually fully cut into individual QFN package 27, which is shown in FIG. 3, where QFN package 27 includes input/output leads 20, lid 22 (i.e., encapsulation) and flange 14 (also referred to as central paddle 14) similar to an ACP package 10 except for input/output leads 20 configuration and other differences discussed below.

Compared to the ACP package 10, QFN package 27 does not require separate window frame 16. In particular, because QFN package 27 does not use window frame 16, it does not have the shunt package capacitances caused by the window frame 16 (like the ACP package 10) and therefore provides low package parasitics. Furthermore, input/output leads 20 and flange 14 are designed in the bare lead frame. This lowers the manufacturing cost by having fewer part counts and manufacturing steps.

A cross-sectional view of a portion of QFN package based device 29 is illustrated in FIG. 4 and includes QFN package 27 is mounted directly on the top side of the carrying PCB 24 since the input/output leads 20 and the central paddle 14 are at the same level. Further, in order to provide added heat dissipation, a via 28 farm is provided that consists of two-dimensional array of closely spaced thru-vias 28 that are vertically placed underneath the central paddle 14 in the carrying PCB 24 for increased heat dissipation to the heat sink 26. However, the via 28 farm is often not adequate to provide necessary heat dissipation even for mid-power range application such that often an embedded copper coin 30 in the carrying PCB 24 may be required for the QFN based device 29 as illustrated in FIG. 5. In particular, the embedded coin 30 (e.g., copper coin 30) allows for heat dissipation from the central paddle 14 to the heat sink 26.

While the embedded coin 30 may enhance heat transfer to the heat sink 26, the embedded coin 30 disadvantageously adds to the manufacturing cost of the radio board. Also, the number of embedded coins 30 needed may add up very quickly in AAS type radio PCB board with multiple transmitter branches. Another un-intended consequence with the embedded coin is that the added layer of interface— the interface layer between the central paddle 14 and the coin 30. In addition to CTE mismatch, this interface can seldomly be soldered perfectly/optimally together and in reality, gas bubble voids are often formed. The addition of these bubble voids increases the overall thermal resistance of the interface, which reduces heat transfer.

### SUMMARY

Some embodiments advantageously provide a circuitry package for use in power amplifiers such as those used in wireless communications. As described above, there are advantages and disadvantages associated with both ACP and QFN packages. One or more embodiments of the present disclosure advantageously describes a circuitry package which combines one or more of the advantages of both ACP and QFN packages while eliminating one or more of their disadvantages. In one or more embodiments, the circuitry package described herein is based on QFN package but is configured with a height offset between the leads and the central paddle. Physically, the circuitry package may look somewhat ‘in between’ or as a mix of the ACP and QFN packages. Starting with the QFN package due to its low parasitics and the low-cost advantages, an offset in height is configured between the leads and the central paddle. This enables the offset QFN package to be mounted with the leads soldered on the top side of the carrying PCB while its central paddle is soldered directly to the heatsink similar to the case for the ACP package, thereby providing excellent heat transfer to the heat sink. This circuitry package or offset QFN package thus combine one or more of the advantages of both ACP and QFN packages while eliminating one or more of their disadvantages.

According to one aspect of the disclosure, a circuitry package that is configured to be positioned on a printed circuit board, PCB, and a heat sink is provided. The circuitry package includes a body portion having a first surface and a plurality of leads on a logical plane and affixed on the first surface of the body portion where the plurality of leads are positionable to make contact with the PCB. The circuitry package includes a central paddle affixed to the body portion and extending in a direction substantially perpendicular to the logical plane where the central paddle is configured to support at least one transistor die near the logical plane and act as a thermal interface between the at least one transistor die and the heat sink.

According to one or more embodiments, a first end of the central paddle is positioned on the logical plane and a second end of the central paddle is positionable on the heat sink. According to one or more embodiments, a first end of the central paddle is positioned at an offset from the logical plane and a second end of the central paddle is positionable on the heat sink. According to one or more embodiments, the plurality of leads are positioned to prevent overlapping between the plurality of leads and the central paddle in the direction perpendicular to the logical plane.

According to one or more embodiments, the central paddle comprises an extended ground conductor. According to one or more embodiments, the circuitry package is positionable in a slot of the PCB. According to one or more embodiments. the plurality of leads are positionable to make contact with signal traces on a first side of the PCB where the heat sink is positioned on a second side of the PCB, and the central paddle is configured to extend through the slot between the first and second sides of the PCB.

According to one or more embodiments, the circuitry package includes at least one extension portion that extends past the logical plane and parallel to the central paddle. According to one or more embodiments, the plurality of leads are configured to be soldered directly to the PCB, and the central paddle is configured to be soldered directly to the heat sink.

According to another aspect of the disclosure, a power amplifier is provided. The power amplifier includes a printed circuit board, a heat sink, and a power transistor package positioned on the printed circuit board, PCB, and the heat sink. The power transistor package includes a body portion having a first surface and a plurality of leads affixed on the first surface of the body portion and on a logical plane where the plurality of leads are positionable to make contact with the PCB. The power transistor package includes a central paddle affixed to the body portion and extending in a direction substantially perpendicular to the logical plane where the central paddle is configured to support at least one transistor die near the logical plane and act as a thermal interface between the at least one transistor die and the heat sink.

According to one or more embodiments, a first end of the central paddle is positioned along the logical plane and a second end of the central paddle is positionable on the heat sink. According to one or more embodiments, a first end of the central paddle that is positioned at an offset from the logical plane and a second end of the central paddle is positioned on the heat sink. According to one or more embodiments, the plurality of leads are positioned to prevent overlapping between the plurality of leads and the central paddle in the direction perpendicular to the logical plane.

According to one or more embodiments, the central paddle comprises an extended ground conductor. According to one or more embodiments, the power transistor package is positionable in a slot of the PCB. According to one or more embodiments, the plurality of leads are positionable to make contact with signal traces on a first side of the PCB where the heat sink is positioned on a second side of the PCB, and the central paddle is configured to extend through the slot between the first and second sides of the PCB.

According to one or more embodiments, the power transistor package includes at least one extension portion that extends past the logical plane and parallel to the central paddle. According to one or more embodiments, the plurality of leads are configured to be soldered directly to the PCB and the central paddle is configured to be soldered directly to the heat sink.

### BRIEF DESCRIPTION OF THE DRAWINGS

A more complete understanding of the present embodiments, and the attendant advantages and features thereof, will be more readily understood by reference to the following detailed description when considered in conjunction with the accompanying drawings wherein:

FIG. 1 is a diagram of components of an ACP package;

FIG. 2 is a cross-section view of an example of a portion of an ACP package based device;

FIG. 3 is a perspective bottom view of an example QFN package;

FIG. 4 is a cross-section view of an example of a portion of a QFN package based device;

FIG. 5 is a cross-section view of another example of a portion of a QFN package based device;

FIG. 6 is a top perspective view of an example circuitry package according to the present disclosure;

FIG. 7 is a perspective view of the bottom of circuitry package according to one or more embodiments of the present disclosure;

FIG. 8 is a front view of circuitry package according to one or more embodiments of the present disclosure;

FIG. 9 is a bottom view of circuitry package according to one or more embodiments of the present disclosure; and

FIG. 10 is a cross-sectional view of a portion of a power amplifier arrangement according to one or more embodiments of the present disclosure;

FIG. 11 is a front view of another circuitry package according to one or more embodiments of the present disclosure; and

FIG. 12 is a front view of another circuitry package according to one or more embodiments of the present disclosure.

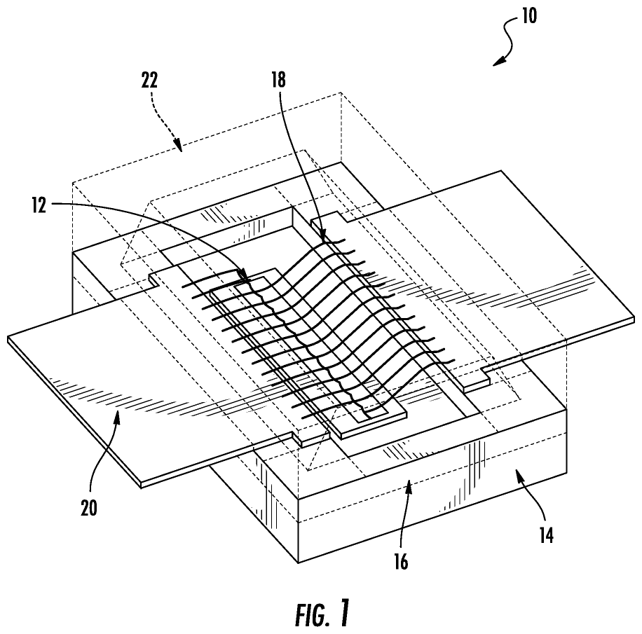

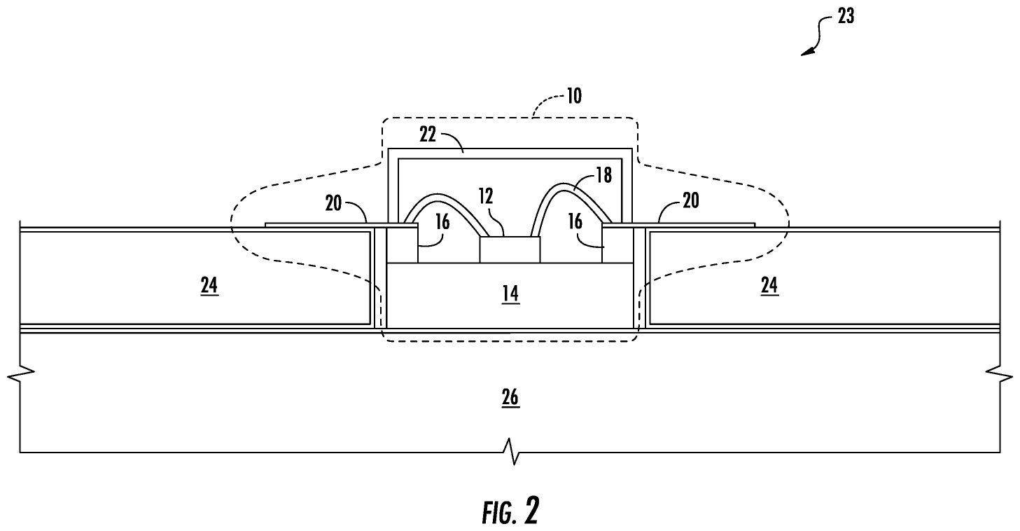

### DETAILED DESCRIPTION

Before describing in detail example embodiments, it is noted that the embodiments reside primarily in combinations of components related to circuitry package for use in power amplifiers such as those used in wireless communications.

Accordingly, components have been represented where appropriate by conventional symbols in the drawings, showing only those specific details that are pertinent to understanding the embodiments so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements. As described above, there are advantages and disadvantages associated with both ACP and QFN type packages. The circuitry package described herein, advantageously combines the advantages of both ACP and QFN packages while eliminating their disadvantages. Further, the circuitry package is applicable to both mid-power and high-power transistors.

Referring again to the drawing figures in which like reference designators refer to like elements, FIG. 6 is a top perspective view of an example circuitry package 32 according to one or more embodiments of the present disclosure. The circuitry package 32 includes body portion 34 having a first surface 36 and a second surface 38. At least a portion of the first surface 36 may be opposite at least a portion of the second surface 38. A plurality of leads 40 (collectively referred to as lead 40) may be affixed on the first surface 36 of the body portion 34. A central paddle 42 may be affixed to the body portion 34. The central paddle 42 is configured to support at least one transistor die 12 and act as a thermal interface between the at least one transistor die 12 and a heat sink 26, as described below. Body portion 34 may further includes at least one extension portion 44 that is configured to extend parallel or substantially parallel to central paddle 42. The at least one extension portion 44 may extend from the first surface 36 and/or a logical plane (described below).

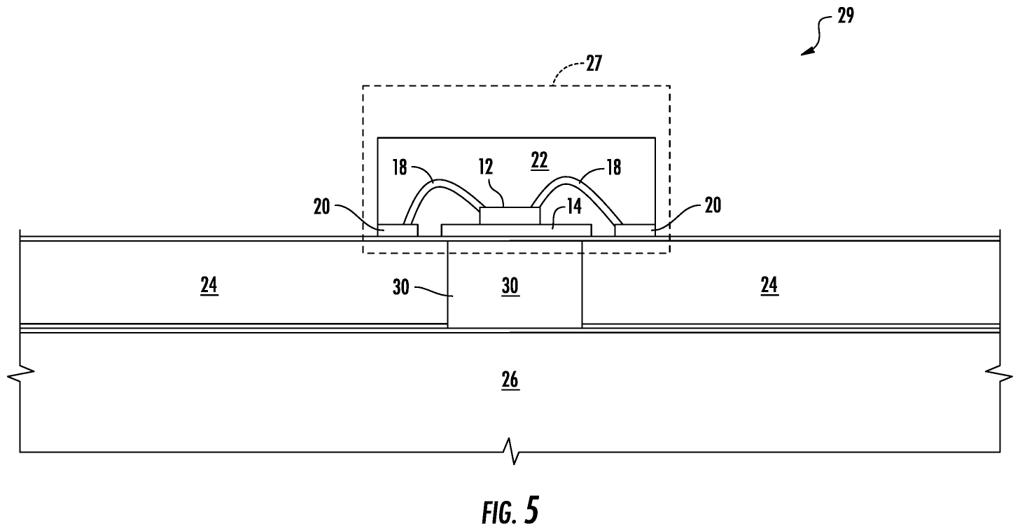

FIG. 7 is a perspective view of the bottom of circuitry package 32 according to one or more embodiments of the present disclosure. The circuitry package 32 of FIG. 7 includes two leads 40 affixed to opposite sides of first surface 36. In one or more embodiments, first surface 36 defines a plurality of recesses (e.g., niches, depression) in which leads 40 are affixed such the one side of leads 40 are flush with first surface 36. Alternatively, the one or more sides of one or more leads may be mounted on first surface 36 absent any recesses.

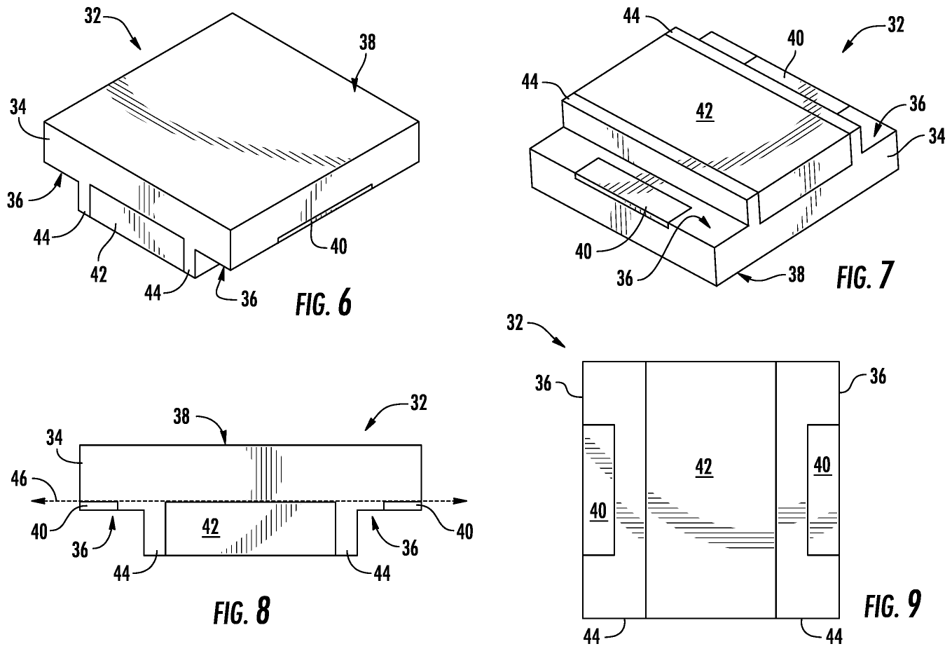

FIG. 8 is a front view of circuitry package 32 according to one or more embodiments of the present disclosure. In particular, FIG. 8 illustrates logical plane 46 where the plurality of leads 40 are positioned on logical plane 46 (i.e., one side of each of the plurality of leads 40 are positioned on the logical plane 46), and central paddle 42 and extension portion 44 are configured to extend in a direction substantially perpendicular to logical plane 46. In one or more embodiments, extension portion 44 extends past the logical plane 46 and parallel to central paddle 42. Also, in the example of FIG. 8, central paddle 42 is positioned on logical plane 46. However, in one or more other embodiments, central paddle 42 is positioned at an offset from logical plane 46. FIG. 9 is a bottom view of circuitry package 32 according to one or more embodiments of the present disclosure.

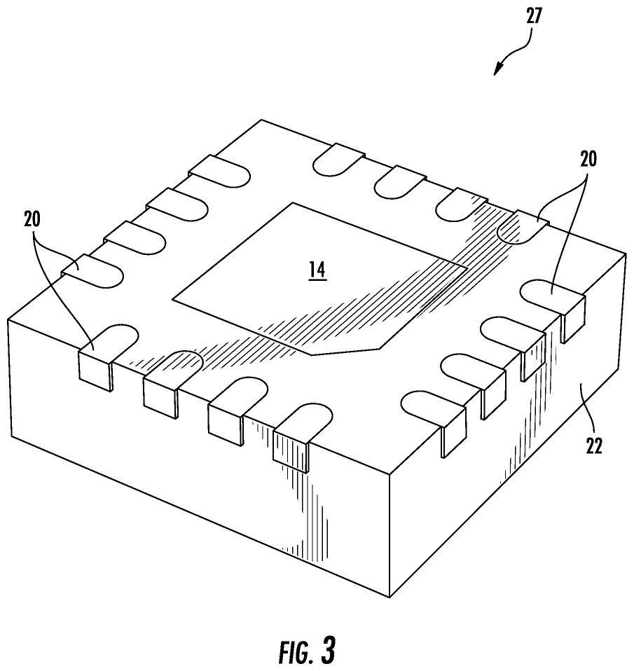

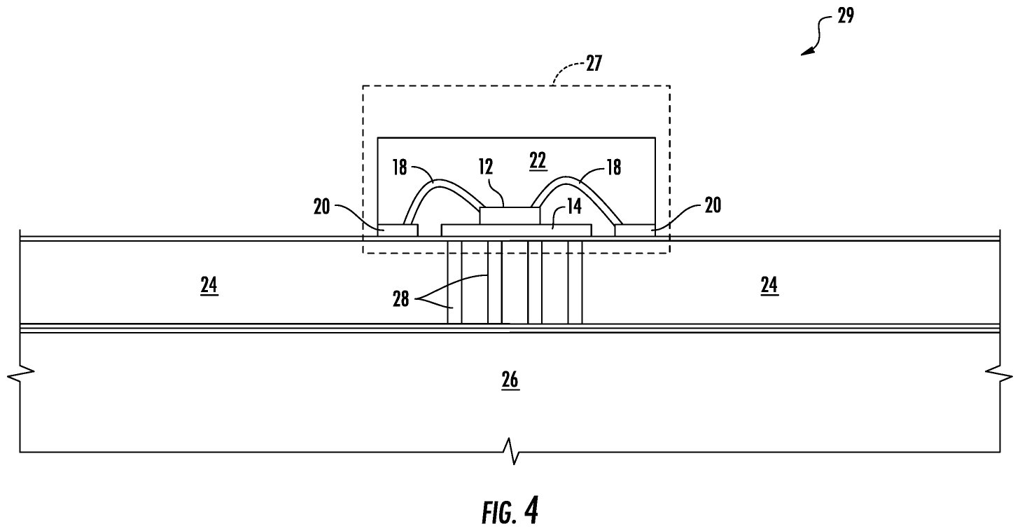

Further, in one or more embodiments, more than two leads 40 may be incorporated into circuitry package 32 in accordance with the principles of the disclosure. For example, additional leads 40 may be added on the one or more sides of first surface 36. Also, circuitry package 32 in FIGS. 6-9 corresponds to a DEN type package (i.e., Dual Flat No-lead—only input and output sides) but the teachings described herein are not limited to only DFN and are not limited to a fixed shape, as circuitry package 32 can be configured to rectangular shape or other shapes and can also accommodate multiple devices/transistor dies with multiple input and output. Further, the shape and/or dimensions of central paddle 42 may be configurable. For example, first surface 36 may extend past central paddle 42 where extension portion 44 is positioned at the perimeter of central paddle 42. This example allows for additional leads 40 to be affixed to first surface 36 along the perimeter of extension portion 44 and/or central paddle 42 similar to the QFN configuration of FIG. 3.

In other words, circuitry package 32 illustrated in FIGS. 6-9 is based on a DFN/QFN type package but has a specifically configured height offset between leads 40 and central paddle 42. Physically, circuitry package 32 may be considered an ‘in between’ version of ACP and QFN type packages.

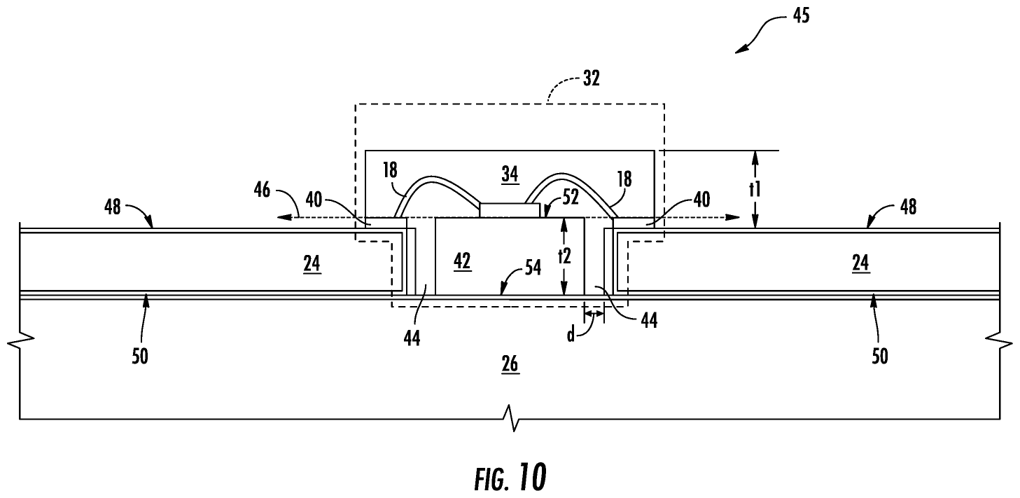

FIG. 10 is a cross-sectional view of an example portion of a power amplifier arrangement 45 (also referred to as power amplifier 45) according to one or more embodiments of the present disclosure. In particular, power amplifier arrangement 45 includes circuitry package 32 positioned on PCB 24 and heat sink 26. For example, the circuitry package 32 may be positioned on PCB 24 and heat sink 26 as part of a power amplifier 45 arrangement, although circuitry package 32 is equally applicable to other device arrangements.

Further, transistor die 12 is positioned and/or affixed to central paddle 42 where central paddle 42 is affixed to body portion 34 such that central paddle 42 is configured to support transistor die 12 near logical plane 46. At least one input and at least one output of transistor die 12 is electronically connected to respective leads 40 where the electrical connection may be accomplished by physically wire bonding the input(s)/output(s) of transistor die 12 to leads 40 via bond wires 18.

Further, the plurality of leads 40 are configured to be soldered directly to PCB 24 and central paddle 42 is configured to be soldered directly to heat sink 26. The plurality of leads 40 are positioned (i.e., positionable) to make contact with signal traces (not shown) on a first side 48 of PCB 24. The heat sink 26 is positioned on a second side 50 of PCB 24.

The mounting of circuitry package 32 may be similar to mounting of an ACP package. A slot with a predefined size may be cut out of PCB in order to “house” at least a portion of circuitry package 32. This allows circuitry package 32 to be mounted with leads 40 soldered on a first side 48 of the carrying PCB 24 while central paddle 42 is soldered directly to heat sink 26 thereby providing good heat dissipation. For example, in one or more embodiments, central paddle 42 is configured to extend through a slot between the first side 48 and second side 50 of PCB 24 such as to act as a thermal interface between transistor die 12 (i.e., at least one transistor die 12) and heat sink 26. That is, circuitry package 32 is positionable in a slot of PCB 24. In one or more embodiments, a first end 52 of central paddle 42 is positioned/positionable on logical plane 46 and a second end 54 of central paddle 42 is positioned/positionable on heat sink 26. In another example, in one or more embodiments, the first side 52 of central paddle 42 is positioned at an offset from logical plane 46 and second end 54 of central paddle 42 is positioned/positionable on heat sink 26. In these examples, the thickness (t2) of central paddle 42 is configured differently such as based on whether the first end 52 of central paddle 42 is to be offset from logical plane 46. Further, increasing the thickness (t2) of central paddle 42 may increase mechanical strength while decreasing the thickness (t2) may provide increased heat dissipation. Further, the plurality of leads 40 are advantageously positioned to prevent overlapping between the plurality of leads 40 and central paddle 42 in a direction perpendicular to logical plane 46 such as to help minimize parasitics.

Further, distance (d) in FIG. 10 corresponds to a width of extension portion 44 where the width may be configured based on one or more desired characteristics such as package strength, size, etc. That is, the distance (d) may correspond to a distance that the bottom molding (circuitry package 32) extends toward an inner edge of lead 40, and can range from zero to the inner edge of lead 40.

In one or more embodiments, a power amplifier 45 is provided. The power amplifier 45 includes printed circuit board 24, heat sink 26, and power transistor package 32 (also referred to as circuitry package 32) positioned on PCB 24 and heat sink 26. The power transistor package 32 includes a body portion 34 having a first surface 36, and a plurality of leads 40 affixed on the first surface 36 of the body portion 34 and on logical plane 46 where the plurality of leads 40 are positionable to make contact with the PCB 24 (i.e., make contact with traces of PCB 24). The power transistor package 32 includes central paddle 42 affixed to body portion 34 and extending in a direction substantially perpendicular to logical plane 46 where central paddle 42 is configured to support at least one transistor die 12 near logical plane 46 and act as a thermal interface between the at least one transistor die 12 and heat sink 26.

According to one or more embodiments, first end 52 of central paddle 42 is positioned along logical plane 46 and second end 54 of central paddle 42 is positionable on heat sink 26. According to one or more embodiments, first end 52 of the central paddle 42 that is positioned at an offset from logical plane 46 and second end 54 of central paddle 42 is positioned on heat sink 26. According to one or more embodiments, the plurality of leads 40 are positioned to prevent overlapping between the plurality of leads 40 and central paddle 42 in the direction perpendicular to logical plane 46.

According to one or more embodiments, central paddle 42 comprises an extended ground conductor. According to one or more embodiments, power transistor package 32 is positionable in a slot of PCB 24. According to one or more embodiments, the plurality of leads 40 are positionable to make contact with signal traces on first side 48 of PCB 24 where heat sink 26 is positioned on second side 50 of PCB 24, and central paddle 42 is configured to extend through the slot between the first and second sides 48, 50 of PCB 24.

According to one or more embodiments, power transistor package 32 includes at least one extension portion 44 that extends past logical plane 46 and parallel to central paddle 42. According to one or more embodiments, the plurality of leads 40 are configured to be soldered directly to PCB 24 and central paddle 42 is configured to be soldered directly to heat sink 26.

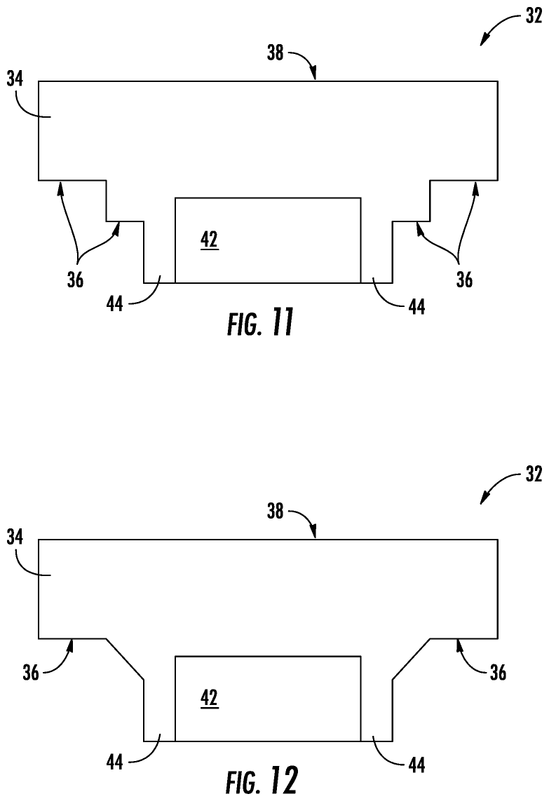

In another example of power transistor package 32, the single step extrusion/extension portion 44 profile can be increased to two or more steps type profile to enhance the package mechanical strength where FIG. 11 illustrates a two steps type profile. Further, other profiles can be used to enhance the package mechanical strength in accordance with the teachings of the present disclosure. In another example, the extrusion/extension portion 44 profile has a slope type profile as illustrated in FIG. 12.

Therefore, as described above, circuitry package 32 for power transistor or power amplifier arrangement 45 is provided where the circuitry package 32 combines the advantages of both ACP and QFN packages such as low cost and low parasitics while at the same time providing increased heat dissipation compared to existing ACP and QFN packages. In particular, the circuitry package 32 advantageously exhibits low package parasitics, which implies improved performance and bandwidth operation compared to the conventional/existing ACP package. At the same time, circuitry package 32 also provides significant cost advantages over the ACP packages.

In particular, comparing circuitry package 32 to the conventional QFN type package, circuitry package 32 provides better heat transfer. In addition, without the need of the embedded coin, circuitry package 32 provides cost saving for the radio board, and also requires one less interface layer between components/elements compared to the QFN type package, which improves thermal conductivity. While circuitry package 32 is described with respect to its use in power transistor packaging or radio board, circuitry package 32 is equally applicable to situations or use cases where enhanced heat transfer may be required.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the embodiments described herein are not limited to what has been particularly shown and described herein above. In addition, unless mention was made above to the contrary, it should be noted that all of the accompanying drawings are not to scale. A variety of modifications and variations are possible in light of the above teachings without departing from the scope of the following claims.

1. A circuitry package that is configured to be positioned on a printed circuit board, (PCB) and a heat sink, the circuitry package comprising:
a body portion having a first surface;
a plurality of leads on a logical plane and affixed on the first surface of the body portion, the plurality of leads being positionable to make contact with the PCB; and
a central paddle affixed to the body portion and extending in a direction substantially perpendicular to the logical plane, the central paddle configured to support at least one transistor die near the logical plane and act as a thermal interface between the at least one transistor die and the heat sink.

2. The circuitry package of claim 1, wherein a first end of the central paddle is positioned on the logical plane and a second end of the central paddle is positionable on the heat sink.

3. The circuitry package of claim 1, wherein a first end of the central paddle is positioned at an offset from the logical plane and a second end of the central paddle is positionable on the heat sink.

4. The circuitry package of claim 1, wherein the plurality of leads are positioned to prevent overlapping between the plurality of leads and the central paddle in the direction perpendicular to the logical plane.

5. The circuitry package of claim 1, wherein the central paddle comprises an extended ground conductor.

6. The circuitry package of claim 1, wherein the circuitry package is positionable in a slot of the PCB.

7. The circuitry package of claim 6, wherein the plurality of leads are positionable to make contact with signal traces on a first side of the PCB, the heat sink is positioned on a second side of the PCB, and the central paddle is configured to extend through the slot between the first and second sides of the PCB.

8. The circuitry package of claim 1, wherein the circuitry package includes at least one extension portion that extends past the logical plane and parallel to the central paddle.

9. The circuitry package of claim 1, wherein the plurality of leads are configured to be soldered directly to the PCB; and
the central paddle is configured to be soldered directly to the heat sink.

10. A power amplifier, comprising:
a printed circuit board;
a heat sink; and
a power transistor package positioned on the printed circuit board, (PCB) and the heat sink, the power transistor package including:
a body portion having a first surface;
a plurality of leads affixed on the first surface of the body portion and on a logical plane, the plurality of leads being positionable to make contact with the PCB; and
a central paddle affixed to the body portion and extending in a direction substantially perpendicular to the logical plane, the central paddle configured to support at least one transistor die near the logical plane and act as a thermal interface between the at least one transistor die and the heat sink.

11. The power amplifier of claim 10, wherein a first end of the central paddle is positioned along the logical plane and a second end of the central paddle is positionable on the heat sink.

12. The power amplifier of claim 10, wherein a first end of the central paddle that is positioned at an offset from the logical plane and a second end of the central paddle is positioned on the heat sink.

13. The power amplifier of claim 10, wherein the plurality of leads are positioned to prevent overlapping between the plurality of leads and the central paddle in the direction perpendicular to the logical plane.

14. The power amplifier of claim 10, wherein the central paddle comprises an extended ground conductor.

15. The power amplifier of claim 10, wherein the power transistor package is positionable in a slot of the PCB.

16. The power amplifier of claim 15, wherein the plurality of leads are positionable to make contact with signal traces on a first side of the PCB, the heat sink is positioned on a second side of the PCB, and the central paddle is configured to extend through the slot between the first and second sides of the PCB.

17. The power amplifier of claim 10, wherein the power transistor package includes at least one extension portion that extends past the logical plane and parallel to the central paddle.

18. The power amplifier of claim 10, wherein the plurality of leads are configured to be soldered directly to the PCB and the central paddle is configured to be soldered directly to the heat sink.
